(19) United States
(12) Patent Application Publication
(10) Pub. No.: US 2007/0290374 A1
(43) Pub. Date: Dec. 20, 2007

(54) Component with Encapsulation Suitable for Wlp and Production Method

(76) Inventor: Pahl Wolfgang, Munich (DE)

Correspondence Address: FISH & RICHARDSON PC, P.O. BOX 1022, MINNEAPOLIS, MN, 55440-1022, US

(21) Appl. No.: 10/591,027

(22) PCT Filed: Jan. 14, 2005
(86) PCT No.: PCT/EP05/00327

§ 371 Date: Jun. 29, 2007

(30) Foreign Application Priority Data
Mar. 4, 2004 (DE) 102004010703.3

(51) Int. Cl. H01L 23/48; H01L 21/44

(52) U.S. Cl. 257/785; 438/654; 257/E21.476; 257/E23.01

(57) ABSTRACT

An electrical component includes a substrate that includes one or more terminal contacts for one or more electrical component structures on a surface of the substrate. The electrical component also includes a cover having a first surface and a second surface. The cover includes one or more terminal pads on the first surface, one or more terminal contacts on the second surface, and electrical throughplatings electrically connecting the terminal pads and the contacts. The cover is on the surface of the substrate. The electrical component also includes a conductive adhesive is in one or more cavities between the substrate and the cover.

A large variety of electrical and micro-electrical components, such as single semiconductors, storage units, processors, SAW and FBAR filters or MEMS are produced with area processors at wafer level. Further, processes, such as layered depositions, photolithographs, selective removal processes or printing processes for a plurality of components are performed at a parallel level. Further, a plurality of similar chips is created on a wafer.

The production expenditure is minimized due to parallel processing at wafer level and the large areas used in this process. This streamlined principle, however, does not end after the separation of the chips, for example, by sawing. Subsequently, the chips are mounted individually in housings and are provided with internal electrical connections. Then the housing is closed and the components are electrically tested for their function.

This process is comparatively time consuming and costly. It also sets limits to progressive miniaturization, because housing and assembly tolerances, as well as dimensions and internal electrical connections, together require much more space than the photolithographic structures of the individual components created during the wafer processes.

Numerous concepts for a so-called WLP (wafer level packaging) have already been developed, especially for semi-conductor devices, which in most cases are based on silicon wafers, in which the encapsulation at wafer level is realized in an area process. The plurality of WLP concepts known from semi-conductor devices is based on bump connections consisting of deposits of solder, which are vapor deposited, printed, or electro-deposited onto the wafer. Another wafer is placed on this bump connection, which, because of its good thermal mechanical adaptability preferably is made of the same material, that is, another silicon wafer. It also is known to place a second wafer directly onto the connection and to make the electrical connections through the second wafer by means of throughplating through the first or second wafer. Overall, WLP concepts used in semi-conductor devices are favored in particular by the following three boundary conditions:

Silicon is a relatively low-cost material and can be used as cover for a wafer with component structures, without resulting in extreme cost increases.

Furthermore, silicon can easily be processed with wet and dry etching processes and mechanically. For this reason, throughplating can easily be produced in silicon and the electrical connections between chip contacts on the surface of the first wafer and external connections of the component can be produced by a simple method.

As a rule, semi-conductor devices are based on purely electronic effects, which are virtually not influenced by mechanical surface loads. For this reason, semi-conductor devices can be directly covered or wrapped at the chip surface. Therefore, additional numerous low-cost processes from plastics technology can be used for the encapsulation. The semi-conductor devices, therefore, can be sealed, extrusion-coated, or covered.

The known WLP concepts, however, cannot be transferred to
components on piezoelectric substrates that are not compatible with a mechanical surface load
micro-mechanical components, whose function is upset by the mechanical load of the surface,
components on large and break-sensitive chips,
components on substrate materials that are difficult to etch and structure,
components on costly substrates, in which a cover made of the same substrate material increases the costs.

The objective of the present invention, therefore, is to specify a new structure of the encapsulated components, which can be produced in a simple wafer-level package (WLP) process.

In accordance with the invention, the foregoing objective is achieved by means of a component according to Claim 1. Improved embodiments of the invention, as well as a new process based on a WLP process, are specified in the subsequent claims.

The invention specifies an electronic component, which is provided in or on a substrate. On the main surface of the substrate, terminal contacts of the electric component structures are provided. The encapsulation encompasses a cover with terminal pads and throughplatings via which the terminal contacts through the cover are connected with the external contacts of the overall component. The cover is located on the so-called “main surface,” so that the terminal pads on the “undersurface” of the cover are located at a distance opposite the terminal pads on the surface of the substrate. A cavity is provided between the contacts, which is completely filled with conductive adhesive, which makes the electrical connection between the substrate and cover and/or between the terminal pads and the terminal contacts. The conductive adhesive provided in the cavities is able to ensure, or at least contribute to, the mechanical connection between substrate and cover.

A component with such an encapsulation is particularly suitable for break-sensitive substrates, since the conductive adhesive connection will not result in a mechanical load on the substrate and/or cover during the encapsulation procedure, so that only very slight tensions based on the encapsulation may occur with the completed component. Furthermore; in order to make an electrical connection, an extreme temperature load of the component are required, which, for example, occurs when producing a solder connection or in wafer-bonding processes. The encapsulation thus is low in tension. It therefore is particularly suitable for components whose characteristics change as a result of mechanically influencing forces or strains. The encapsulation can be performed with many different substrate and covering materials. Preferably, the substrate and cover should be balanced in terms of their thermal properties, in order to minimize the thermal strains, which occur during the operation of the component at an elevated temperature.

Preferably, the cavities open towards the outer edge of the component, which intersects the cavities. At least, however, the cavities are configured in the immediate vicinity of an outer edge.

In an improved embodiment of the invention, an intermediate layer is configured between the substrate and the cover, in which the cavities are configured. The intermediate layer can be structured and solely serves to form the cavities in said layer. Preferably it consists of a material which can easily be shaped, especially a synthetic material. Said material may cover the entire main surface, except the cavities. The intermediate layer may also comprise several cavities in which the component structures can be arranged.

Of particular advantage is an enclosed frame structure, which is provided between the substrate and the cover in the area of the outer edge of the component, which comprises recesses pointing towards the inside, which are limited by the top and bottom of the substrate and the cover, thus forming the said cavities. In this sandwich-type configuration, a flush contact is provided between substrate, frame structure, and cover, which on the one hand ensures a load-free cover on the substrate, and on the other hand a certain tightness in the inside of the frame structure. Preferably, a cavity is formed inside the enclosed frame structure between the substrate and cover, in which the sensitive component structures can be configured. The frame structure encloses the component structures so that the terminal pads outside the frame are provided in the aforesaid recesses and/or cavities.

Preferably, the cover is formed as a printed circuit board, which, for example, comprises two dielectric layers. On the top or undersurface of the cover and between the dielectric layers, circuit elements comprising structured metallizations are preferably arranged. The metallizations, which are provided in the various levels, can be interconnected via throughplatings. The external connections preferably are interconnected on the surface of the cover pointing away from the substrate.

The cover may be a single or multi-layered synthetic material, glass, ceramics or other dielectric materials. A preferred material, a glass-fiber reinforced printed circuit board material (FR4), which at least in one axis is thermo-mechanically very well adjusted to the piezoelectric substrate made of lithium niobate.

Within the meaning of the invention, a conductive adhesive is understood to be a material, which can be processed in a liquid condition or with adequately low viscosity, but is conductive at the component's operating temperature, especially a conductive synthetic material, which hardens and simply solidifies. Preferably, the conductive adhesive is a reaction resin, which hardens at low temperatures and is filled with electrically conductive particles. Low hardening temperatures, for example below 100° C., can be achieved with two-component reaction resins, in which their resin and hardening components are mixed shortly prior to application. Another option is to use light hardening or UV hardening resins. This option exists especially when the substrate or cover in the required spectral range is sufficiently permeable and the adhesive, therefore, can be exposed from the outside or be irradiated. Overall, a low temperature hardening conductive adhesive is able to perform the adhesion in such a way that no thermal tensions will occur after the adhesive has hardened. This, for example, can also be achieved by means of microwave irradiation.

A preferred application of an inventive component are components operating with acoustic waves, especially SAW filters and FBAR components. The inventive encapsulation configuration also is an advantage to MEMS components, especially in connection with a frame structure, which provides a cavity for the component structures. Particularly advantageous is the invention for realizing SAW and FBAR components, if said components operate at low frequencies (e.g., below 100 MHz), and therefore require particularly large substrates. Because of the porosity of the known, crystalline, piezoelectric materials, substrates made of these materials are particularly break-sensitive, and previously were used exclusively in an encapsulated and protected form in housings and for contacting by means of wire-bonding techniques. Compared with a component installed in a housing, an inventive component has the advantage of considerably lower height, which makes the components accessible to new applications, especially mobile components used in information and communications technology, e.g., cell phones and PDAs.

The inventive components can be produced quite simply and elegantly by a new process. The principle according to the invention is to fit the substrate with the component structures on top of each another, so that the terminal pads and the terminal contacts are located opposite each other, are separated from one another by the height of the frame structure or the intermediate layer described in the above.

At wafer level, the conductive adhesive then is injected by a system of channels in a configuration in which each channel interconnects several cavities, preferably is configured between the components, and traverses the component in a straight line. During the injection, all channels and the cavities connected with said channels are filled in one phase, and the electrical connections allocated to the cavities are created between the substrate and the cover.

In a second phase, the separation of the components is so performed that the cavities, which are electrically short-circuited via the filled channels, are electrically separated by means of a suitable saw cut. This is achieved preferably by means of approximately straight-lined channels, which expand at the corresponding intervals towards said cavities. During the separation, the saw cut can be performed either along the edge of the channel or preferably the width of the saw cut is to be so adjusted that it corresponds to the width of the channel. During the cut, which is coincident with the channel, the entire channel and the inserted conductive adhesive is removed during the saw cut. Other separating processes, such as laser cutting or water jet cutting, of course, are other alternatives.

Several component regions with component structures are provided on the wafer. Preferably, the channels are provided between two rows of adjacently configured component regions. Depending on the size of the wafer used for the substrate, several preferably parallel channels are provided. The channels can be created both on the surface of the substrate wafer and on the surface of the cover or on both surfaces. The channels can be formed in the form of recesses in the corresponding surfaces. Preferably an additional material for producing the channels is applied onto one or both surfaces, preferably in the form of frame structures, which surround the component regions. Several adjacent component regions, which abut with their frame structures, form a side wall of the channel with a lateral edge of the frame structure, preferably with a longitudinal edge. The other side wall is formed by another row, which abuts with the component region in its frame structures. On at least one side of the channel, the frame structures are recessed to form cavities. This means that each channel only connects the cavities with a row of component regions, while the opposite row of component regions, which forms the other channel wall, preferably is straight-lined and configured without recesses. This will facilitate the subsequent reliable cutting of the filled channel for electrical separation.

The frame structures, as mentioned above, are formed on one or both interconnecting surfaces. For this purpose, a suitable material is applied, preferably over a large area, for example, a plastic film is glued on, laminated or fused. Another option is to apply the plastic layer by means of a varnish, for example, by spin-on deposition, casting and, in particular, curtain casting. Preferably a light-sensitive material is used, which can be structured in the form of photoresist.

As an improvement, the plastic film, from which the frame structure is to be formed, is planarized. By this method, the substrate secondary units can be balanced, and the upper edges on one level can be created for the frame structures. If both the substrate and the cover have topographic levels, for example, circuit board conductors or other component-related structures, it is preferable to create a corresponding frame structure with planarized upper edges both on the upper surface of the substrate and on the undersurface of the cover.

The structuring is effected by imaging exposure during which the plastic film for the frame structure preferably is interlinked during exposure and becomes insoluble compared with a development in the exposed regions. After the structuring of the frame structure, the substrate and cover are aligned towards one another, arranged above one another, and preferably provided with adhesive and glued down at the upper edges of the frame structure. The gluing has the advantage that by this method a corresponding configuration of substrate and cover in relative exact position to one another is fixed relatively fast. When injecting the conductive adhesive, no additional external fixing of the configuration is required, which means a considerable reduction in processing costs, and a quick release of the component operating with high positioning accuracy.

Alternatively, the channels or parts thereof can be worked into the substrate or covering surface, for example, by sawing, etching, or lasering.

The injection of conductive adhesive can be performed parallel via all channels simultaneously. It is an advantage to combine all channels or groups, in order to create a single or only a few injection points. Preferably, the injection is pressurized and is supported by a vacuum applied at the open other end of the channels as well. Another advantage is reducing the viscosity of the conductive adhesive by injection at an elevated temperature. Temperatures are preferable, which are still inadequate for hardening the conductive adhesive. Another option is to use a thermoplastic compound as conductive adhesive, which is injected in melted condition and ultimately re-hardens during the cooling process. The electric conductivity of the conductive adhesive may be of an intrinsic nature or be produced by adding conductive fillers. Suitable conductive particles, for example, are metal powder or carbon-containing particles, such as soot or graphite.

Compared with other contacting processes, which are based on printed, stamped, or dispensed conductive adhesive volumes, the major advantage of the present invention is that it offers an extremely simple, streamlined, and safe application of the conductive adhesive, which nevertheless enables a high degree of accuracy and reproducibility of the geometry of individual contact points in keeping with the precision of the preferred phototechnically structured frame.

In the following, the invention is explained in detail by means of embodiments and the related figures. The figures are diagrammatic, rather than according to scale.

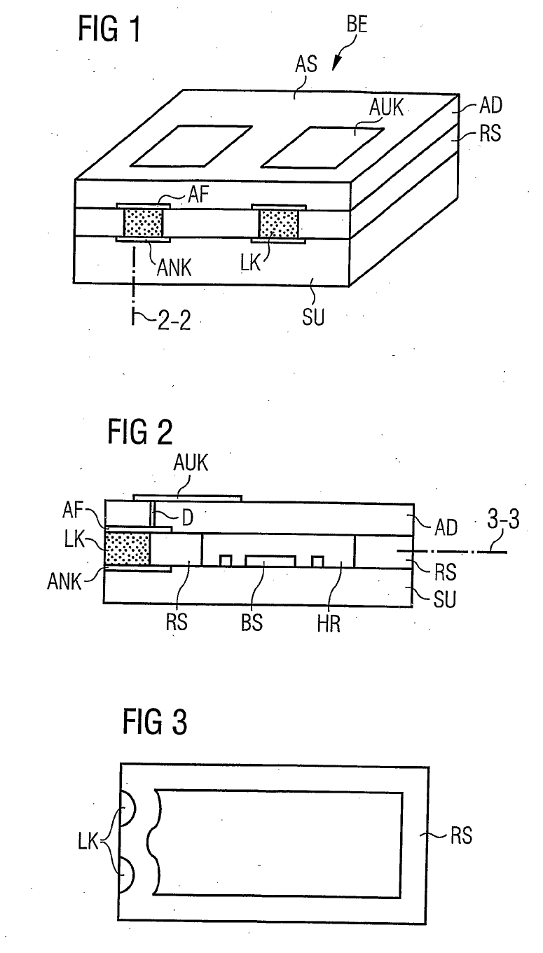

FIG. 1 shows a perspective view of an inventive component.

FIG. 2 shows the component in a first sectional view.

FIG. 3 shows the component in a second sectional view.

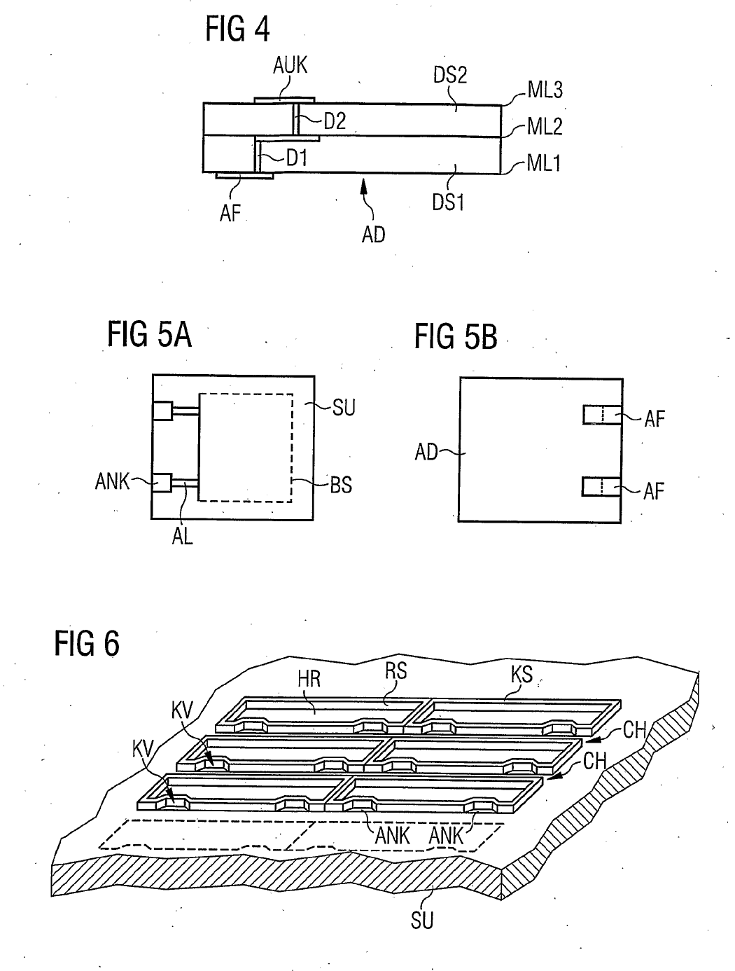

FIG. 4 shows a cover in cross-section.

FIG. 5 shows the substrate and cover in horizontal projection.

FIG. 6 shows a wafer with frame structures.

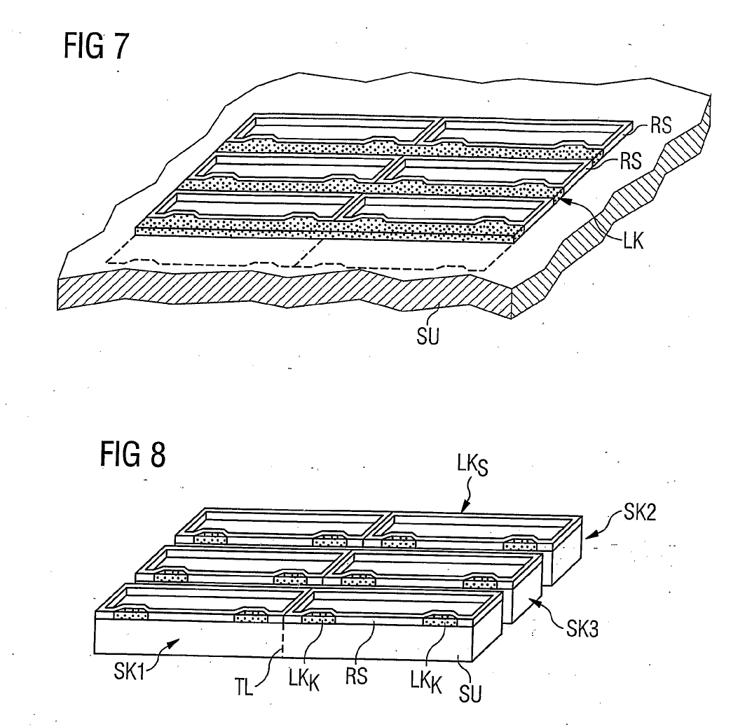

FIG. 7 shows the wafer with channels filled with conductive adhesive.

FIG. 8 shows the wafer after the saw cuts have been performed.

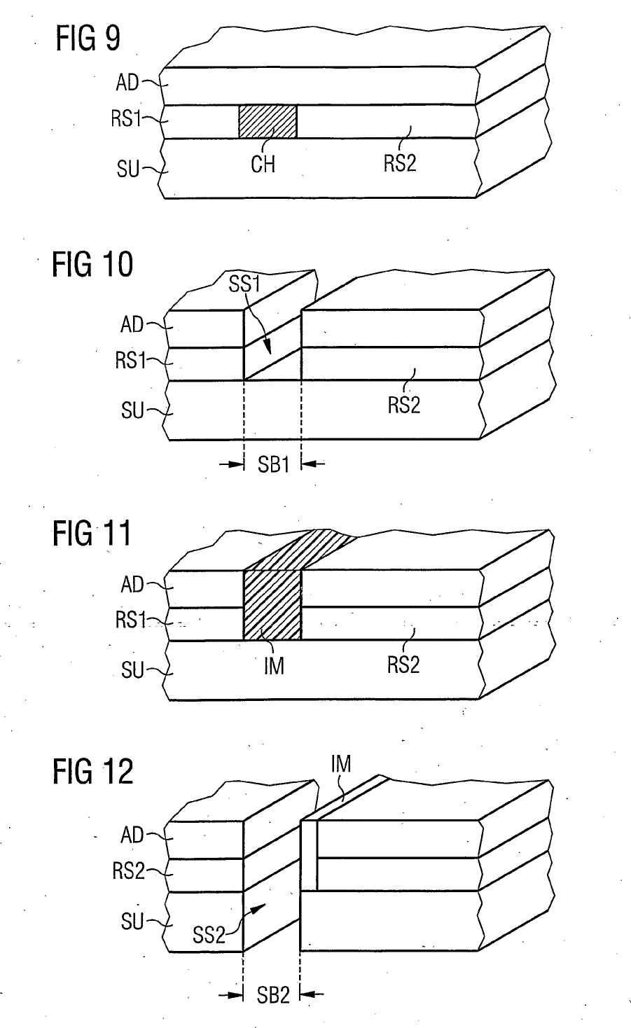

FIGS. 9 to 12 show a component during different process phases of another embodiment shown in a perspective partial view.

FIG. 1 shows a perspective view of a simple embodiment of an inventive component. The component BE comprises a substrate SU on or in which electrical component structures (not shown) are realized. On the top of the substrate SU, a frame structure RS is configured, which serves as a spacer for the cover AD, which rests on the frame structure RS. The cover AD comprises terminal pads AF, which in the component BE are provided directly opposite the terminal contacts ANK. The electrical connection between the terminal pads and the terminal contacts is realized by means of a conductive adhesive LK, which fills a cavity within the component. It is an improvement to realize the cavity within the frame structure RS. On the outside AS of the cover, outside contacts AUK are configured, which are connected with the terminal pads on the undersurface of the cover AD via throughplatings (not shown).

FIG. 2 shows the same component in a schematic cross-section through sections 2-2 across the substrate surface. This presentation clearly indicates that the conductive adhesive LK provided in the cavity is arranged between the cover AD, the frame structure RS and the substrate SU, which form part of the cavity. The figure is shown in an improved embodiment in which the frame structure runs along the component edges and limits a cavity HR on both sides which is enclosed at the bottom by the substrate SU and at the top by the cover AD. Examples of the component structures BS are shown in the cavity, preferred component structures which are sensitive against mechanical influences. Furthermore, a throughplating D, which connects the terminal pad AF with the terminal contact AUK, also is exemplary.

FIG. 3 shows a cross-section through the same component along section 3-3, which at the level of the frame structure runs parallel with the substructure surface. This shows that the frame structure RS is enclosed and at least at one side has recesses, which form part of the cavity filled with the conductive adhesive LK.

FIG. 4 shows a schematic cross-section of a cover AD, which is formed as a multi-layered printed circuit board. It consists of two dielectric layers DS1, DS2, and three metal insulating levels ML1, ML2, and ML3, which are configured on the undersurface of the cover between the dielectric layers DS1, DS2 and on the outside of the cover AD. Each metallization level ME is so structured that in each metallization level metallic areas, strip conductors, and strip conductor structures are formed, which represent an interconnecting level for producing an integrated interconnection. Another option is to integrate passive components within the multi-layered cover, especially resistors, capacitors, and inductors.

In a schematic horizontal projection, FIG. 5a shows a substrate SU. It comprises the component structures BS as indicated, which are connected via connecting lines AL with the terminal contacts ANK. The terminal contacts ANK are provided directly at the edge of the substrate or at least in the direct vicinity of the edge of the substrate. The component structures can be protected with a relatively thin (less than 100 nm), passivating dielectric layer, in which the terminal contacts ANK are excluded from this passivated layer.

The metallization for the terminal contacts ANK preferably consist of a base metallization, for example, from aluminum or a predominantly aluminum-containing alloy. This base metallization can be coated with one or several additional metal films, which can be selected from Cu, Ti, Ni, Ag, Au, Pd and Pt.

FIG. 5b shows a schematic horizontal projection of the undersurface of the cover AD, which at least comprises metallic terminal pads AF, which are arranged correspondingly to the terminal contacts ANK of the substrate SU. Furthermore, on the undersurface of the cover AD, additional circuit elements of the metallization level ML1 (refer to FIG. 4) can be configured.

The production of an inventive component is explained in the following by means of FIGS. 6 to 8, which show various processing phases in a schematic diagram.

An inventive component can be produced completely at wafer level in a WLP (wafer level packaging) process. The component structures for a plurality of components is produced in or on the substrate SU—in this case a wafer. Each component region, in which all component structures of a component are configured, now is provided with a frame structure RS, which encloses the component region. For this purpose, it is an improvement, if a material suitable for photostructuring is applied to the wafer surface and structure photolithographically. Preferably a film suitable for photostructuring is laminated and, if necessary, planarized subsequently, for example, by means of a roller at an elevated temperature and under a suitable roller pressure. The application of a corresponding photoresist is suitable for this purpose.

FIG. 6 shows the configuration after completion of the frame structure RS. According to the invention, the frame structure is to be so designed that a channel CH remains between each two rows of adjacent component regions, which extends in a straight line across the entire wafer and has an opening at each of the two wafer edges. On at least one outer edge, preferably at the longitudinal edge of the frame structure of a component region, the channel CM extends to a cavity KV in which the frame structure RS at this point comprises a recess. In the improved embodiment shown here, the cavities KV are disposed only at one longitudinal side of each component region, in which all component regions are configured adjacently in the same direction. In the cross-section parallel to the substrate surface, the cavity preferably comprises a flow-enhancing profile, in order to minimize the flow resistance during the subsequent injection of the conductive adhesive and to enable the smooth filling of the cavities. The figure shows a section of the cavities with beveled edges. Another option is rounded structures. The number of cavities per component region is optional, preferably, however, at least two cavities for the corresponding electric terminal contacts are provided, which are arranged within the recess. The geometry of the channels CH is selected as a function of the flow properties of the applied conductive adhesive. A typical height of the channels, for example, is around 15 μm, but the channels may also have a height of 10 to 300 μm. Correspondingly, the width, for example, is selected at 100 μm, in which lower widths of 20 μm or larger widths of up to 300 μm are optional as a function of the selected separation process. All channels CH of the wafer preferably are arranged parallel to one another. As an improvement, transpositions are avoided, that is, channel structures that are x- or y-shaped. Consequently this facilitates a bubble-free filling with conductive adhesive.

In the next phase, a cover AD is prepared, which comprises corresponding terminal pads AF to the terminal contacts ANK. If necessary, the cover AD also may comprise a second frame structure corresponding to the frame structure RS of the substrate SU, in order to provide a planar surface on the substrate in the contact region to the first frame structure. However, this also may be achieved, if the cover on the undersurface is provided with a planarization level in which the terminal pads AF are exposed. This enables balancing the topographic differences, which, for example, may range from 15 to 30 μm with strip conductors. Subsequently, the cover AD is placed upon the frame structure RS, which are bonded together, for example, by means of an adhesive level KS, which is applied to one or both bonding points, preferably to the upper edge of the frame structure RS. The purpose of the cover is that at least the channel CH and the cavities KV at the top are covered in order to provide an enclosed line/channel system for the conductive adhesive.

In the next phase, the conductive adhesive is injected at the external openings of the channels CH, preferably by means of overpressure to the injection side, and a vacuum is applied parallel at the other open end of the channel. The injection for each channel CH can be performed individually, but it is also possible to inject the conductive adhesive by means of suitable components onto the wafer at all channels simultaneously. This complete or group-like connection of the channels can also be provided in the layout of the frame structure, for example, at the edge of the wafer.

FIG. 7 shows the component after the injection of the conductive adhesive LK, which fills the channel CH and cavities KV bubble-free and completely. In order to obtain a better overview, the cover AD is not shown, so that the component regions, frame structures, and channels filled with the conductive adhesive LK are shown in a horizontal projection, which normally are enclosed and/or covered by the cover. After injection, the conductive adhesive LK can be hardened.

In the next phase, the components are separated. This, for example, can be achieved by sawing along the edges of the component regions. The saw cuts preferably are so performed that the frame structure largely is retained and/or that the cavity enclosed by the structure is not opened. It also is important that the saw cut, which runs parallel to the channels, opens the cavities KV, but eliminates the short circuit by means of the conductive adhesive provided in the channels (CH). In FIG. 8, this is shown for example by means of the front cutting edge SK1 in which the conductive adhesive exclusively remains in the cavities opened towards the cutting edge following the saw cut. Concerning the opposite cutting edge, which in the figure, for example, is the rear cutting edge SK2, one option is that the stripe-shaped conductive adhesive structure LK_{S} remains. This is unproblematic, since at this point no electrical short circuit can occur between the various cavities and/or the terminal pads provided underneath said cavities. Optionally, the saw cut can be performed, so that the cutting width of the saw at least corresponds to the width of the channel CH, so that during the cutting process, the conductive adhesive is removed for the entire width of the channel.

For the sake of providing a better overview, FIG. 8 does not show the cover placed on the frame structure RS, which is cut through as well during the separation. After performing another saw cut along the indicated separation line TL, individual components are produced as shown in FIG. 1

In the above-described process, components are produced in which the component edge cuts the cavity, so that the conductive adhesive provided in said cavities is exposed to the outside. In the following, a process variant is introduced by means of FIGS. 9 to 12, which also is to be performed at wafer level, by means of which outside insulated conductive adhesive-filled cavities can be produced.

FIG. 9 shows the configuration in a process phase corresponding to FIG. 7 in a diagrammatic cross-section, that is, after the channels CH have been filled with conductive adhesive. It shows a channel, which on both sides is limited by a first and second frame structure RS1, RS2.

In a first saw cut, which, for example, is performed starting at the top of the cover AD and at least reaching the surface of the substrate SU, the cavities are electrically separated. Preferably the cutting width SB1 corresponds to the first saw cut of the channel width.

In a next phase, the incision of this first saw cut preferably is filled completely with an insulating compound IM, for example, with a reaction resin or an insulated paste.

Subsequently, in order to separate the components, a second saw cut of the width of the saw SB2, preferably using a narrower saw width, is made through the entire configuration parallel to the first saw cut, so that at one side of the incision a strip of insulating material IM remains.

FIG. 11 shows the configuration after the first saw cut has been filled with the insulating compound IM.

Subsequently, the separation of the components, a second cut of saw width SB2, preferably with a narrower saw blade, is performed through the entire configuration parallel to the first saw cut, so that on one side of the incision a strip of insulating material IM remains. This strip insulates the cavities opened during the first saw cut and/or the conductive adhesive LK disposed in said cavities. By this method, one obtains a component whose component structures opposite the cutting edge are electrically insulated. Undesired electrical short circuits during contact with conductive structures can thus be avoided.

In a modification of this process, the opened channel is not completely filled with the insulating material (IM). On the contrary, in the area of the first saw cut only a relatively thin layer of insulating material is deposited or applied.

Another option is to seal at least the cutting edges of the frame structure (RS) with a coating, which, after the separation, is created by means of the application of varnish or chemical vapor disposition. An inorganic modified polymer is particularly suitable as varnish. Polymers such as Parylene® can be applied by means of chemical vapor disposition, or a dielectric layer, such as an SiO₂ layer, can be applied. This, for example, can be performed after the separation, in which the components can be held on an adhesive film on which they may be seated with the surfaces that carry the outside contacts (AUK).

The inventive process offers an improved application for producing large area components and especially for producing SAW components or FBAR components, which operate with acoustic waves. The structure of said components, which is sensitive against mechanical influence, can be used advantageously in the cavity formed by the frame structure, and thus can be mechanically protected. Further, during the production process an excessive load on the substrate wafer, as it might occur with the known flip chip configuration, is avoided as well. Therefore, the inventive process also is suitable for producing large area components with brittle or break-sensitive substrates. The components, which operate with acoustic waves, especially have large dimensions and previously could only be packaged and protected in housings through individual processing. The SAW filters produced according to the invention therefore offer a preferred application for TV, radio, and video, as well as multimedia.

The aforesaid components operating with acoustic waves are suitable for applying substrates onto the undersurface in variable processing phases prior to separation, which is able to balance the thermal strains that build up in the remaining sandwiched configuration consisting of substrate, frame structure, and cover, and, therefore, can be produced especially from the same material as the cover. Such a balancing layer offers components operating with acoustic waves the advantage that interfering bulk waves can be attenuated and their reflection at the undersurface can be suppressed. This effect is particularly interfering with components operating at lower frequencies and thus high wavelengths in the area of the substrate thickness, so that amplified volume waves in that area are able to propagate up to the substrate undersurface. For this reason, and because the encapsulated component according to the invention is mechanically stable, the substrate prior to coating can be reduced in thickness from the undersurface of the substrate. Another option is using a thinning wafer from the outset, since the inventive structure stabilizes the components mechanically, which in particular reduces the risk of breakage during separation. Inventive components can be produced on wafers of less than 500 μm thickness, and which, for example, have a thickness ranging between 250 and 400 μm, without increasing the volume of waste resulting from wafer fracture.

1. An electrical component comprising:
a substrate comprising one or more terminal contacts for one or more electrical component structures on a surface of the substrate,
a cover having a first surface and a second surface, the cover comprising:
one or more terminal pads on the first surface;
one or more outside contacts on the second surface; and
electrical throughplatings electrically connecting the terminal pads on the first surface and the outside contacts on the second surface; wherein the cover is on the surface of the substrate; and
a conductive adhesive in one or more cavities between the substrate and the cover, the conductive adhesive forming an electrical connection between the terminal contacts on the substrate and the terminal pads.

2. The electrical component of claim 1, wherein the cavities extend from an outer edge of the component.

3. The electrical component of claim 1, further comprising an interface layer between the substrate and the cover, wherein the cavities are in the interface layer.

4. The component of claim 1, further comprising an enclosed frame structure between the substrate and the cover in an area of an outer edge of the electrical component, the enclosed frame structure comprising one or more recesses that form the cavities.

5. The component as of claim 4, wherein:
the enclosed frame structure encloses the electrical component structures,
the terminal contacts on the substrate are outside the frame structure, and
the substrate is in direct contact with a first side of the enclosed frame structure and the cover is in direct contact with a second side of the enclosed frame structure.

6. The component of claim 1, wherein the cover includes a plurality of dielectric layers and a plurality of metallizations on a dielectric layer or among the dielectric layers respectively.

7. The component of claim 1, wherein the conductive adhesive comprises a reaction resin configured to harden at low temperatures, the reaction resin including electrically conducting particles.

8. A process for producing a component, the component including a substrate that includes component regions that comprise component structures and terminal contacts and a cover having a surface, the cover including terminal pads on the surface; the method for producing the component comprising:
arranging the cover such that at least some of the terminal pads are located substantially opposite corresponding ones of the terminal contacts in cavities, wherein the cavities of a plurality of the component regions are connected via channels;
forming an electrical contact between terminal contacts and corresponding terminal pads by injecting a conductive adhesive into the channels until the cavities are substantially filled with the conductive adhesive; and
separating the component regions such that electrical connections between the cavities are interrupted.

9. The process of claim 8, further comprising:
arranging frame structures between the substrate and the cover such that a particular frame structure encloses a particular component region and the terminal contacts for the particular component region are located outside the particular frame structure, wherein the channels (CH) are formed between the frame structures of adjacent component regions and the channels are covered by the substrate and the cover.

10. The process of claim 8, wherein the conductive adhesive comprises a reaction resin that includes electrically conducting particles.

11. The process of claim 9, further comprising:
producing the frame structures by applying a photoresist onto one or both of the the substrate and the cover; and
patterning the photoresist.

12. The process of claim 9, further comprising:
producing the frame structures on a surface of the substrate; and
bonding the frame structures to the cover.

13. The process of claim 9, further comprising planarizing the frame structures.

14. The process of claim 8, wherein injecting the conductive adhesive comprises injecting the conductive adhesive under pressure into the channels.

15. The process of claim 8, wherein separating the component regions further comprises:
sawing the component to separate the component regions, wherein sawing comprises:
forming saw cuts in a direction substantially parallel to the channels such that the conductive adhesive remains in the cavities and such that the channels are separated from cavities.

16. The process of claim 15, further comprising sealing one or more edges of the frame structure with a coating.

17. The process of claim 16, wherein sealing one or more edges of the frame structure comprises sealing one or more edges of the frame structure using a method selected from the group consisting of applying a varnish and using chemical vapor deposition.

18. The process of claim 8, wherein:
the cavities are only at one longitudinal edge of the component regions; and
the channels are substantially parallel to the one longitudinal edge and are arranged in a substantially straight line.

19. The process of claim 15, wherein sawing to separate the component regions further comprises:
making a first saw cut with a first cutting width to electrically separate cavities filled with the conductive adhesive from one another and to form a channel,
filling the channel with insulating material; and
making a second saw cut with a second cutting width at a distance to the cavities in the first saw cut, the second cutting width being less than the first cutting width.

20. The process as defined in claim 19, wherein filling the channel with insulating material comprises filling less than all of the channel with a single layer of the insulating material.

21. The process of claim 15 wherein the cover comprises a printed circuit board comprised of synthetic material and the method further comprises applying a thermal mechanically adjusted synthetic layer to a back side of the substrate.

22. The electrical component of claim 1, wherein the cavities are arranged in a vicinity of an outer edge of the electrical component.

23. The process of claim 9, further comprising:
producing the frame structure on a surface of the cover; and
bonding the frame structure to the substrate.

24. The process of claim 9, further comprising:
producing a first portion of the frame structure on a surface of the a substrate;
producing a second portion of the frame structure on a surface of the cover; and
bonding the first portion of the frame structure to the second portion of the frame structure.
